(19) United States
(12) Patent Application Publication
(10) Pub. No.: US 2026/0052807 A1
(43) Pub. Date: Feb. 19, 2026

(54) III-V COMPOUND SEMICONDUCTOR LIGHT-EMITTING ELEMENT AND METHOD OF PRODUCING III-V COMPOUND SEMICONDUCTOR LIGHT-EMITTING ELEMENT

(71) Applicant: DOWA Electronics Materials Co., Ltd., Chiyoda-ku, Tokyo (JP)

(72) Inventors: Yuta KOSHIKA, Akita-shi, Akita (JP); Yoshitaka KADOWAKI, Akita-shi, Akita (JP)

(73) Assignee: DOWA Electronics Materials Co., Ltd., Chiyoda-ku, Tokyo (JP)

(21) Appl. No.: 19/107,027

(22) PCT Filed: Aug. 28, 2023
(86) PCT No.: PCT/JP2023/031046

§ 371 Date: Feb. 27, 2025

(30) Foreign Application Priority Data
Sep. 1, 2022 (JP) 2022-139579
Aug. 25, 2023 (JP) 2023-137516

(51) Int. Cl. H10H 20/824; H10H 20/01; H10H 20/812; H10H 20/816

(52) U.S. Cl. CPC H10H 20/824; H10H 20/013; H10H 20/812; H10H 20/8162

(57) ABSTRACT

Provided is a III-V compound semiconductor light-emitting element having good light emission output relative to injected power compared to conventional light-emitting elements. The III-V compound semiconductor light-emitting element includes an n-type cladding layer, a light-emitting layer, and a p-type cladding layer in stated order and includes an undoped electron blocking layer between the light-emitting layer and the p-type cladding layer. The light-emitting layer has a layered structure in which a barrier layer and a well layer are repeatedly stacked. At a conduction band, a band gap of the electron blocking layer is larger than band gaps of the barrier layer and the p-type cladding layer, and the band gap of the p-type cladding layer is larger than the band gap of the barrier layer. At a valence band, a band gap of the electron blocking layer is between band gaps of the barrier layer and the cladding layer.

### TECHNICAL FIELD

The present disclosure relates to a III-V compound semiconductor light-emitting element and a method of producing a III-V compound semiconductor light-emitting element.

### BACKGROUND

III-V compound semiconductors such as InGaAsP, InGaAlAs, and InAsSbP are used as semiconductor materials of semiconductor layers in semiconductor light-emitting elements. Through composition ratio adjustment of a light-emitting layer formed using a III-V compound semiconductor material, it is possible to adjust the light emission wavelength of a semiconductor light-emitting element over a wide range from green to infrared. For example, semiconductor light-emitting elements that are infrared-emitting with a light emission wavelength in an infrared region of wavelengths of 750 nm or more are widely used in applications such as sensors, gas analysis, surveillance cameras, and communications.

Patent Literature (PTL) 1 discloses a light-emitting element that includes an n-type cladding layer, an active layer, and a p-type cladding layer in this order in a semiconductor laminate where a plurality of InGaAsP III-V compound semiconductor layers containing at least In and P are stacked and in which the p-type cladding layer has a thickness of 2,400 nm to 9,000 nm.

### CITATION LIST

### Patent Literature

PTL 1: JP2019-186539A

### SUMMARY

### Technical Problem

In recent years, there has been demand for further improvement of light emission efficiency of light-emitting elements. The inventors conducted research with the aim of further improving light emission output relative to injected power over the structure in PTL 1. Accordingly, an object of the present disclosure is to obtain a III-V compound semiconductor light-emitting element having good light emission output relative to injected power compared to conventional light-emitting elements.

### Solution to Problem

As a result of extensive research conducted diligently with the aim of achieving the object described above, the inventors completed the present disclosure as set forth below. Specifically, primary features of the present disclosure are as follows.
(1) A III-V compound semiconductor light-emitting element comprising an n-type cladding layer, a light-emitting layer, and a p-type cladding layer in stated order, wherein
an undoped electron blocking layer is included between the light-emitting layer and the p-type cladding layer,
the light-emitting layer has a layered structure in which a barrier layer and a well layer are stacked repeatedly,
(i) at a conduction band, a band gap (Ec) of the electron blocking layer is larger than a band gap (Ecb) of the barrier layer and a band gap (Ecs) of the p-type cladding layer, and the band gap (Ecs) of the p-type cladding layer is larger than the band gap (Ecb) of the barrier layer, and
(ii) at a valence band, a band gap (Ev) of the electron blocking layer is between a band gap (Evb) of the barrier layer and a band gap (Evs) of the p-type cladding layer.
(2) The III-V compound semiconductor light-emitting element according to the foregoing (1), wherein the electron blocking layer and the p-type cladding layer have a different principal group V element from each other.
(3) The III-V compound semiconductor light-emitting element according to the foregoing (1) or (2), wherein an undoped spacer layer is included between the electron blocking layer and the p-type cladding layer, and the p-type cladding layer and the spacer layer have the same principal group V element as each other.
(4) The III-V compound semiconductor light-emitting element according to any one of the foregoing (1) to (3), wherein the spacer layer has a thickness of 300 nm or less.
(5) The III-V compound semiconductor light-emitting element according to any one of the foregoing (1) to (4), wherein the electron blocking layer and the p-type cladding layer are adjacent.
(6) A method of producing the III-V compound semiconductor light-emitting element according to any one of the foregoing (1) to (5), comprising:
a step of forming the n-type cladding layer;
a step of forming the light-emitting layer on the n-type cladding layer;
a step of forming the electron blocking layer on the light-emitting layer; and
a step of forming the p-type cladding layer on the electron blocking layer.

### Advantageous Effect

According to the present disclosure, it is possible to provide a III-V compound semiconductor light-emitting element having good light emission output relative to injected power compared to conventional light-emitting elements and a method of producing the same.

### BRIEF DESCRIPTION OF THE DRAWINGS

In the accompanying drawings:

FIG. 1 illustrates one example of a band structure of a light-emitting layer and semiconductor layers before and after the light-emitting layer in a present embodiment as calculated using simulation software;

FIG. 2 is a schematic cross-sectional view illustrating one form of principal parts of a III-V compound semiconductor light-emitting element according to the present disclosure;

FIG. 3 is a schematic cross-sectional view illustrating a III-V compound semiconductor light-emitting element according to one embodiment of the present disclosure;

FIG. 4 is a schematic cross-sectional view illustrating a method of producing a III-V compound semiconductor light-emitting element according to one embodiment of the present disclosure using a bonding method;

FIG. 5 illustrates a band structure of a light-emitting layer and semiconductor layers before and after the light-emitting layer in Example 1, Comparative Example 1, and Comparative Example 6 as calculated using simulation software; and

FIG. 6 illustrates diffusion of a dopant of a p-type cladding layer into a light-emitting layer in Example 3.

### DETAILED DESCRIPTION

The following describes various definitions in the present specification in advance of describing embodiments according to the present disclosure.

### <III-V Compound Semiconductor Layers>

Firstly, when referring simply to a “III-V compound semiconductor” in the present specification, the composition thereof is represented by a general formula: (InₐGa_{b}Al_{c})(PₓAs_{y}Sb_{z}). The following relationships hold for the composition ratios of the various elements.

For the group III elements, c=1−a−b, 0≤a≤1, 0≤b≤1, and 0≤c≤1.

For the group V elements, z=1−x−y, 0≤x≤1, 0≤y≤1, and 0≤z≤1.

A III-V compound semiconductor layer according to the present disclosure contains one type or two or more types of group III elements selected from the group consisting of Al, Ga, and In and one type or two or more types of group V elements selected from the group consisting of As, Sb, and P.

Moreover, in a case in which a III-V compound semiconductor layer contains one type or two or more types of group III elements selected from the group consisting of Al, Ga, and In and one type of group V element selected from the group consisting of As, Sb, and P, the composition ratios of elements in the composition of the III-V compound semiconductor layer have the following relationships.

For the group III elements, c=1−a−b, 0≤a≤1, 0≤b≤1, and 0≤c≤1.

For the group V elements, any one of x, y, and z is 1, and the other two of x, y, and z are 0.

Furthermore, when a III-V compound semiconductor layer in a light-emitting layer contains one type of group V element, it is preferable that the III-V compound semiconductor layer contains two or more types of group III elements, and more preferable that the III-V compound semiconductor layer contains three types of group III elements. Also, a III-V compound semiconductor layer in an electron blocking layer according to the present disclosure preferably contains three or more types of elements. The reason for this is that when two or fewer types of elements, in total, are adopted as group III and group V elements in the electron blocking layer, this limits selection choice of compositions that enable the creation of band gap positional relationships according to the present disclosure between the electron blocking layer and a light-emitting layer and between the electron blocking layer and a p-type cladding layer.

The electron blocking layer and the p-type cladding layer preferably have a different principal group V element from each other. When layers are said to have a different principal group V element from each other, this means that when one selected from x, y, and z exceeds 0.5 for group V elements in one of the layers, another of x, y, z (i.e., a different one of x, y, and z from that selected for the one layer) exceeds 0.5 for group V elements in the other layer. The composition ratios of these different group V elements are each preferably 0.6 or more, and more preferably 0.8 or more in order to inhibit diffusion of a dopant in the p-type cladding layer described further below. For example, in a case in which the principal group V element in the p-type cladding layer is P, the principal group V element in the electron blocking layer can be As.

### <Lattice Constant Based on Composition>

The following describes calculation of lattice constants of mixed crystals in the present specification. Although there are two types of lattice constants in a vertical direction (growth direction) and a horizontal direction (in-plane direction) relative to the plane of a substrate, a value for the vertical direction is used in the present specification. First, a simple lattice constant for the mixed crystal is calculated in accordance with Vegard's law. Using an InGaAsP system (i.e., a general formula: (InₐGa_{b})(PₓAs_{y})) as an example for illustrative purposes, a physical property constant A_{abxy} (lattice constant according to Vegard's law) is calculated from the following equation <1> based on physical property constants Bₐₓ, B_{bx}, B_{ay}, and B_{by} (literature value lattice constants shown below in Table 1) for the four binary mixed crystals that are the basis for the quasi-quaternary mixed crystal in a case in which each composition ratio (solid phase ratio) is known.

$${A}_{abxy} = a \times x \times {B}_{ax} + b \times x \times {B}_{bx} + a \times y \times {B}_{ay} + b \times y \times {B}_{by} \qquad \text{<1>}$$

TABLE 1

| | Lattice | | |
|---|---|---|---|
| | constant [nm] | C₁₁ | C₁₂ |
| InP | 0.58688 | 10.22 | 5.76 |
| GaP | 0.54512 | 14.12 | 6.253 |
| InAs | 0.60584 | 8.329 | 4.526 |
| GaAs | 0.56533 | 11.88 | 5.38 |

Next, with regards to elastic constants C₁₁ and C₁₂, elastic constants C_{11abxy} and C_{12abxy} for (InₐGa_{b})(PₓAs_{y}) are also calculated in the same way as in equation <1>.

When the lattice constant of a growth substrate is taken to be as, a (vertical direction) lattice constant a_{abxy} that takes into account lattice distortion can be determined using the following equation <2> by taking into account lattice distortion based on the elastic properties of the semiconductor crystal.

$${a}_{abxy} = {A}_{abxy} - 2 \times ( {a}_{s} - {A}_{abxy} ) \times {C}_{12 abxy} / {C}_{11 abxy} \qquad \text{<2>}$$

Since InP is used as a growth substrate in a present embodiment, the lattice constant of InP should be used as the lattice constant as of the growth substrate.

In the case of a quasi-ternary mixed crystal, when a general formula: (InₐGa_{b}Al_{c})(As) is taken as an example, the band gap Eg_{abcy} and the lattice constant A_{abcy} according to Vegard's law can be calculated from the following equations <3> and <4>.

$$[ Math . 1 ]$$

$${Eg}_{abcy} = \frac{\{ a \times b \times {E}_{aby} + b \times c \times {E}_{bcy} + c \times a \times {E}_{acy} \}}{( a \times b + b \times c + c \times a )} \qquad \text{<3>}$$

$${A}_{abcy} = a \times {B}_{ay} + b \times {B}_{by} + c \times {B}_{cy} \qquad \text{<4>}$$

Note that in a case in which the III-V compound semiconductor is a ternary, pentanary, or hexanary III-V compound semiconductor, the composition wavelength and the lattice constant can be determined by modifying the equations according to the same reasoning as described above. Moreover, in the case of a binary III-V compound semiconductor, the aforementioned literature values can be used.

### <Calculation of Band Gap at Conduction Band-Side and Valence Band-Side of Each Layer Based on Composition>

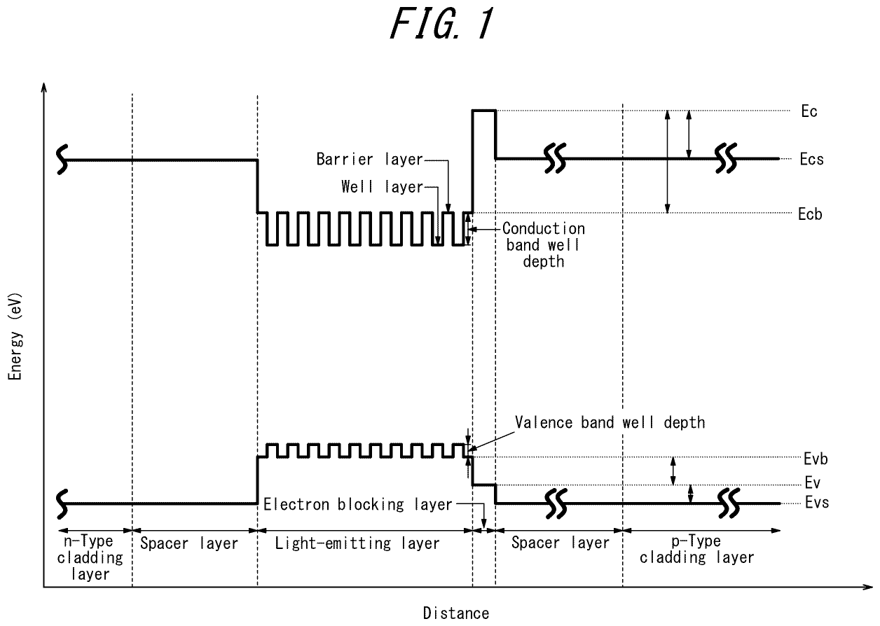

Simulation software (SiLENSe_Version 6.4) produced by STR Japan K.K. was used to calculate a band structure by inputting values for composition ratios of layers in an initial setting state. FIG. 1 illustrates an example of the band structure of a light-emitting layer, an electron blocking layer, spacer layers, and cladding layers according to a present embodiment as calculated using this simulation software. In addition to the band structure being displayed when using this simulation software, the band gap (Ec, Ev) of the electron blocking layer, the band gap (Ecb, Evb) of a barrier layer of the light-emitting layer, and the band gap (Ecs, Evs) of the spacer layers and the cladding layers are also calculated. Note that since FIG. 1 illustrates a case in which the band gaps of the spacer layers and the cladding layers are the same, the band gaps of the spacer layers and the cladding layers are aligned in FIG. 1. In the drawing, the units of band gap energy are eV, reference signs beginning with “Ec” indicate values of band gap energies at the conduction band, and reference signs beginning with “Ev” indicate values of band gap energies at the valence band. Moreover, in addition to the band structure being displayed when using this simulation software, the energy band gap Eg (eV) of each layer, a well depth that is the band gap difference between a barrier layer and a well layer at the conduction band-side, and a well depth that is the band gap difference between the barrier layer and the well layer at the valence band-side are also calculated. Moreover, the composition wavelength of each layer represented by a wavelength λ calculated from the energy band gap Eg by the following equation <5>:

$$Eg = 123 9.8 / λ \qquad \text{<5>}$$

was also calculated.

### <Film Thicknesses and Compositions of Layers>

The overall thickness of formed layers can be measured using an optical interference film thickness meter. Moreover, the thickness of each layer can be calculated using an optical interference film thickness meter and cross-section observation of a grown layer through a transmission electron microscope. Furthermore, in a case in which layers have small thicknesses of the order of several nanometers like in a superlattice structure, the thickness can be measured using TEM-EDS, and the composition ratios (solid phase ratios) of layers in the present specification are taken to be values obtained through SIMS analysis. The composition ratios (solid phase ratios) of each layer in a light-emitting layer, the composition ratios of an electron blocking layer, and the composition ratios of a spacer layer in the present specification are taken to be values obtained by implementing SIMS analysis (quadrupole type) in a thickness direction of the light-emitting layer after exposing the vicinity of an uppermost layer of the light-emitting layer through etching (from an n-layer-side). Note that for SIMS analysis results, a value of the average element concentration in a half-thickness range at a central part of each layer in the thickness direction is adopted. In production, a layer having target composition ratios can be stacked by using growth conditions that are determined such as to give the target composition ratios by calculating solid phase ratios using a lattice constant according to XRD measurement and a value determined through conversion of a central emission wavelength according to PL measurement to Eg for a layer grown as a single film.

<p-, n-, i-Types and Dopant Concentrations>

In the present specification, a layer that functions electrically as a p-type is referred to as a p-type layer and a layer that functions electrically as an n-type is referred to as an n-type layer. On the other hand, a layer to which a specific impurity such as Si, Zn, S, Sn, or Mg is not intentionally added and that does not function electrically as a p-type or an n-type is referred to as an “i-type” or as “undoped”. A III-V compound semiconductor layer that is undoped may contain impurities that are unavoidably mixed in during a production process. Specifically, when a layer has a low dopant concentration (for example, less than 7.6×10¹⁵ atoms/cm³), the layer is treated as “undoped” in the present specification. Values for the impurity concentrations of Si, Zn, S, Sn, Mg, and the like are taken to be values according to SIMS analysis. Likewise, values for impurity concentrations (“dopant concentrations”) of n-type dopants (for example, Si, S, Te, Sn, Ge, O, etc.) in a light-emitting layer are also taken to be values according to SIMS analysis. Also note that values for dopant concentrations are each taken to be the value for dopant concentration at the thickness direction center of that layer because values for dopant concentrations change significantly in proximity to the boundaries of semiconductor layers.

The following provides a detailed, illustrative description of embodiments of the present disclosure with reference to the drawings. Note that constituent elements that are the same are, as a rule, allotted the same reference numbers, and repeated description thereof is omitted. Also note that in the drawings, ratios of the height and width of a substrate and each layer are illustrated in a manner that is exaggerated relative to the actual ratios thereof in order to facilitate description.

### (III-V Compound Semiconductor Light-Emitting Element)

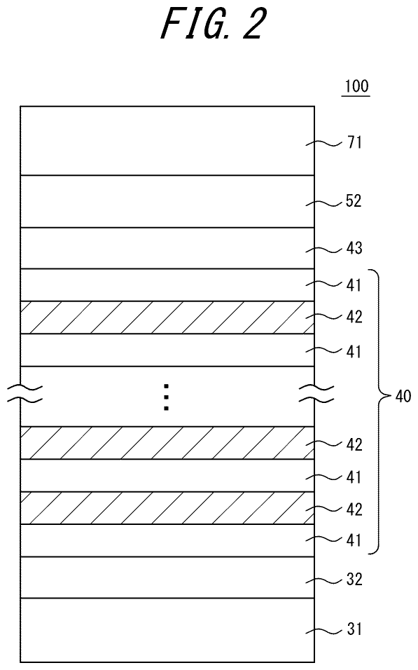

FIG. 2 illustrates principal parts of a III-V compound semiconductor light-emitting element 100 according to the present disclosure. The III-V compound semiconductor light-emitting element 100 includes an n-type cladding layer 31, a light-emitting layer 40, and a p-type cladding layer 71 in stated order, and also includes an undoped electron blocking layer 43 between the light-emitting layer 40 and the p-type cladding layer 71. The light-emitting layer 40 has a layered structure in which a barrier layer 41 and a well layer 42 are repeatedly stacked. The barrier layer 41 and the well layer 42 have different composition ratios to each other.

In the III-V compound semiconductor light-emitting element 100, (i) at a conduction band, a band gap (Ec) of the electron blocking layer 43 is larger than a band gap (Ecb) of the barrier layer 41 and a band gap (Ecs) of the p-type cladding layer 71, and the band gap (Ecs) of the p-type cladding layer 71 is larger than the band gap (Ecb) of the barrier layer 41. Moreover, in the III-V compound semiconductor light-emitting element 100, (ii) at a valence band, a band gap (Ev) of the electron blocking layer 43 is between a band gap (Evb) of the barrier layer 41 and a band gap (Evs) of the p-type cladding layer 71. The inventors discovered experimentally that by designing the III-V compound semiconductor light-emitting element 100 such as to satisfy these conditions (i) and (ii), it is possible to improve light emission output relative to injected power of the III-V compound semiconductor light-emitting element 100 over that of conventional semiconductor light-emitting elements, and it is possible to achieve higher light emission output relative to injected power at least when comparing III-V compound semiconductor light-emitting elements having a light-emission wavelength in the same wavelength region.

With regards to the relationships between the band gaps of the electron blocking layer 43, the barrier layer 41, and the p-type cladding layer 71 at the conduction band and the valence band, when the band gap design conditions according to the present disclosure set forth above are expressed using inequality signs, the relationships are Ec>Ecb and Ec>Ecs for the conduction band and are Evb>Ev and Ev>Evs for the valence band. Each difference between band gap values indicated by the inequality signs of these design conditions can be set as 0.030 eV or more. Moreover, in band gap relationships of the conduction band, the value of Ec−Ecb is preferably 0.120 eV or more, and more preferably 0.150 eV or more. The value of Ec−Ecs is preferably 0.060 eV or more, and more preferably 0.120 eV or more. Moreover, the value of Ec−Ecb is preferably at least 0.030 eV larger than the value of Ec−Ecs (i.e., the value of Ecs−Ecb is preferably 0.030 eV or more). Furthermore, in band gap relationships of the valence band, the value of Evb−Ev is preferably 0.060 eV or more. Moreover, the value of Ev−Evs is preferably 0.060 eV or more.

When providing the undoped electron blocking layer 43, it is preferable that the electron blocking layer and the p-type cladding layer have a different principal group V element from each other in order to design the electron blocking layer 43 such that the band gap (Ev) thereof at the valence band is between the band gap (Evb) of the barrier layer and the band gap (Evs) of the p-type cladding layer. In a case in which the electron blocking layer and the p-type cladding layer have the same principal group V element as each other, setting the band gap (Ec) of the electron blocking layer 43 at the conduction band as larger than the band gap (Ecs) of the p-type cladding layer 71 normally results in the band gap (Ev) at the valence band being smaller than the band gap (Evs) of the p-type cladding layer, and thus makes it difficult to position the band gap (Ev) at the valence band between the band gap (Evb) of the barrier layer and the band gap (Evs) of the p-type cladding layer.

The principal group V element in the barrier layer 41 and the well layer 42 preferably differs from that in the p-type cladding layer 71, and this principal group V element is more preferably As or Sb. Even more preferably, limiting the group V element to one type makes it possible to eliminate a phenomenon of group V element diffusion at a boundary between the well layer 42 and the barrier layer 41. Moreover, although the effect is weaker than that obtained through interposition of the electron blocking layer, setting the principal group V element as a different element to that in the p-type cladding layer 71 can also inhibit diffusion of a p-type impurity in the light-emitting layer.

Various alterations can be made to the extent that the effects according to the present disclosure are displayed. For example, instead of a case in which a laminate formed of the barrier layer 41 and the well layer 42 encompasses the entire quantum well structure as in the present embodiment, the laminate formed of the barrier layer 41 and the well layer 42 may alternatively constitute part of a quantum well structure, and peaks and troughs may be provided in the band structure through combination with another laminate.

### <Light-Emitting Layer>

The following further describes details of configurations of the light-emitting layer 40 in embodiments of the present disclosure.

### —Film Thickness—

Although no limitations are placed on the film thickness of the overall light-emitting layer 40, the film thickness thereof can be set as 0.1 μm to 8 μm, for example. Moreover, although no limitations are placed on the film thickness of each layer among the barrier layer 41 and the well layer 42 in the laminate of the light-emitting layer 40, the film thickness thereof can be set as approximately not less than 1 nm and not more than 15 nm, for example. The film thicknesses of these layers may be the same or different. Moreover, the film thicknesses of barrier layers 41 in the laminate may each be the same or different. The same applies to the film thicknesses of well layers 42. However, a case in which the film thicknesses of barrier layers 41 are the same and the film thicknesses of well layers 42 are the same and in which the light-emitting layer 40 has a superlattice structure is one preferred form in the present disclosure.

### —Number of Stacked Groups—

The following refers to FIG. 2. Although no limitations are placed on the number of groups of both a barrier layer 41 and a well layer 42, the number of groups can be set as not less than 3 groups and not more than 50 groups, for example. One extremity of the laminate can be a barrier layer 41 and the other extremity of the laminate can be a well layer 42. In this case, the number of groups of a barrier layer 41 and a well layer 42 is denoted as n groups (n is a natural number).

Moreover, one extremity of the laminate may be a barrier layer 41, a repeated structure of a well layer 42 and a barrier layer 41 may then be provided, and the other extremity of the laminate may be a barrier layer 41. Alternatively, both extremities may conversely be a well layer 42. In this case, the number of groups of a barrier layer 41 and a well layer 42 is denoted as n (n is a natural number), and the number of groups can be said to be n.5 groups. In FIG. 2, both extremities of the laminate are illustrated as being a barrier layer 41.

### —Composition Ratios—

So long as conditions relating to the composition wavelength difference and the lattice constant difference are satisfied, no limitations are placed on the composition ratios a, b, c, x, y, and z of the III-V compound semiconductor represented by a general formula (InₐGa_{b}Al_{c})(PₓAs_{y}Sb_{z}) in each layer among the barrier layer 41 and well layer 42. However, the ranges from which these composition ratios are selected are preferably set such that ratios of lattice constant differences between a growth substrate and the barrier layer 41 and the well layer 42 in the light-emitting layer 40 are each 1% or less in order to inhibit deterioration of crystallinity of the light-emitting layer 40. In other words, it is preferable that a value obtained when an absolute value of the lattice constant difference between the growth substrate and the barrier layer 41 is divided by an average value for the growth substrate and the barrier layer 41 and a value obtained when an absolute value of the lattice constant difference between the growth substrate and the well layer 42 is divided by an average value for the growth substrate and the well layer 42 are each 1% or less. For example, when an InP substrate is used as a growth substrate in a case in which the central emission wavelength is not less than 1,000 nm and not more than 1,900 nm, the composition ratio a of In can be set as not less than 0.0 and not more than 1.0, the composition ratio b of Ga can be set as not less than 0.0 and not more than 1.0, the composition ratio c of Al can be set as not less than 0.0 and not more than 0.35, the composition ratio x of P can be set as not less than 0.0 and not more than 0.95, the composition ratio y of As can be set as not less than 0.15 and not more than 1.0, and the composition ratio z of Sb can be set as not less than 0.0 and not more than 0.7 in each layer. The composition ratios should be set from within these ranges as appropriate such that conditions relating to the composition wavelength difference and the ratio of lattice constant difference are satisfied. The central emission wavelength mentioned above is merely one example. For example, in the case of an InGaAsP semiconductor or an InGaAlAs semiconductor, the central emission wavelength can be set within a range of not less than 1,000 nm and not more than 2,200 nm, is preferably set as 1,300 nm or more, and is more preferably set as 1,400 nm or more. In a case in which Sb is included, the central emission wavelength can set as infrared of an even longer wavelength (11 μm or less).

### —Dopant—

Although no limitations are placed on a dopant in each layer of the light-emitting layer 40, it is preferable that the barrier layer 41 and the well layer 42 are each an i-type in order to reliably obtain the effects according to the present disclosure. However, each of the layers may be doped with an n-type or p-type dopant.

<n-Type Cladding Layer>

The n-type cladding layer 31 is provided at one side of the light-emitting layer 40. The composition of a III-V compound semiconductor of the n-type cladding layer 31 should be set as appropriate in accordance with the composition of a III-V compound semiconductor of the light-emitting layer 40. For example, an n-type InP layer can be used in a case in which the light-emitting layer 40 is formed of an InGaAsP semiconductor or an InGaAlAs semiconductor. The n-type cladding layer 31 may have a single layer structure or may be a composite layer including a plurality of stacked layers. The thickness of the n-type cladding layer can, for example, be not less than 1 μm and not more than 5 μm.

<p-Type Cladding Layer>

The p-type cladding layer 71 is provided at the other side of the light-emitting layer 40. The composition of a III-V compound semiconductor forming the p-type cladding layer 71 should be set as appropriate in accordance with the composition of a III-V compound semiconductor of the light-emitting layer 40. For example, the III-V compound semiconductor can be p-type AlInP. The p-type cladding layer 71 may have a single layer structure or may be a composite layer including a plurality of stacked layers. The film thickness of the p-type cladding layer 71 is not specifically limited and can be set as not less than 1 μm and not more than 5 μm.

### <Electron Blocking Layer>

In FIG. 2, the electron blocking layer 43 is provided directly on and adjacent to the light-emitting layer 40. The electron blocking layer 43 is typically provided between a quantum well structure (MQW) functioning as the light-emitting layer 40 and the p-type cladding layer 71 so as to be used as a layer for increasing electron injection efficiency by causing damming of electrons and injection of electrons into the light-emitting layer 40 (into a well layer in the case of an MQW). Conventionally, when such an electron blocking layer 43 has been designed to have a large band gap Ec at a conduction band in order to improve light emission output, it has normally been the case that a band gap (potential) Ev thereof at a valence band has decreased. However, the inventors discovered that contrary to such technical common knowledge, light emission output relative to injected power can be improved by, in a situation in which an undoped electron blocking layer 43 is provided, designing the electron blocking layer 43 such that the band gap (potential) Ev at the valence band rises. Note that the thickness of the electron blocking layer 43 is, for example, preferably set as not less than 6 nm and not more than 60 nm, more preferably set as not less than 10 nm and not more than 50 nm.

When providing the undoped electron blocking layer 43, it is preferable that the electron blocking layer and the p-type cladding layer have a different principal group V element from each other in order to design the electron blocking layer 43 such that the band gap (Ev) thereof at the valence band is between the band gap (Evb) of the barrier layer and the band gap (Evs) of the p-type cladding layer as previously described. However, even with layers having a different principal group V element from each other, light-emission efficiency will decrease in a situation in which epitaxial growth cannot be performed in a state with a small lattice constant difference because defects arise due to the lattice constant difference. Therefore, it is preferable that composition range adjustment is made such that a lattice constant difference between the light-emitting layer and the electron blocking layer and a lattice constant difference between the electron blocking layer and the p-type cladding layer are each 0.54% or less. For example, when a case in which the light-emitting layer 40 is InGaAlAs having a central emission wavelength of 1,300 nm or more, the p-type cladding layer 71 is InP, and element design is performed based on the lattice constant of InP is taken as an example, the electron blocking layer 43 can be InₐGa_{b}Al_{c}As having As as a principal group V element, the composition ratio a of In can be not less than 0.51 and not more than 0.57, the composition ratio b of Ga can be not less than 0.0 and not more than 0.13, and the composition ratio c of Al can be not less than 0.46 and not more than 0.49. Design conditions also change depending on the light-emitting layer and the p-type cladding layer and should be set as appropriate such as to satisfy the conditions according to the present disclosure.

### <Spacer Layers>

An undoped spacer layer 52 having the same principal group V element as the p-type cladding layer 71 may be formed between the electron blocking layer 43 and the p-type cladding layer 71 (i.e., at a p-side of the semiconductor layered structure). In this case, it is preferable that the electron blocking layer 43 and the spacer layer 52 have a different principal group V element from each other. The thickness of the spacer layer 52 is preferably 320 nm or less, more preferably 200 nm or less, and even more preferably 100 nm or less. The spacer layer 52 may have the same composition as the p-type cladding layer 71.

By providing the spacer layer 52, it is possible to inhibit diffusion of a dopant of the p-type cladding layer 71 into the light-emitting layer 40, and, as a result, it is possible to improve light emission output. Moreover, the provision of the electron blocking layer 43 in the present disclosure means that an adequate dopant diffusion prevention effect can be maintained even with a thin spacer layer 52, thus enabling further improvement of light emission output compared to a conventional III-V compound semiconductor light-emitting element including a thick spacer layer.

For example, even when the principal group V element is the same such as when an i-type InP spacer layer is adopted as the spacer layer 52 with respect to a p-type InP cladding layer, the absence of an impurity provides an effect of preventing dopant diffusion from the p-type InP cladding layer. Moreover, in a situation in which the electron blocking layer 43 according to the present disclosure that has a different principal group V element is formed, this electron blocking layer provides a strong dopant diffusion prevention effect, and thus makes it possible to adopt a thinner spacer layer 52 than is conventionally the case. Furthermore, since light emission output can be improved by adopting a thinner spacer layer 52 through the electron blocking layer 43 according to the present disclosure, the thickness of the spacer layer 52 is preferably 320 nm or less, more preferably 200 nm or less, and even more preferably 100 nm or less. It is also preferable that a spacer layer 32 is provided at the n-side of the light-emitting layer 40. The n-side spacer layer 32 can be an undoped III-V compound semiconductor layer. For example, an i-type InP spacer layer is preferably adopted as the n-side spacer layer 32. Although no limitations are placed on the thickness of the n-side spacer layer 32, the thickness thereof may be set as not less than 5 nm and not more than 500 nm, for example.

Note that the electron blocking layer 43 and the p-type cladding layer 71 may be adjacent to each other. Even in this case, it is preferable that the electron blocking layer 43 and the p-type cladding layer 71 have a different principal group V element from each other. The dopant diffusion prevention effect through the electron blocking layer 43 described above is anticipated to enable a thinner spacer layer 52 than is conventionally the case.

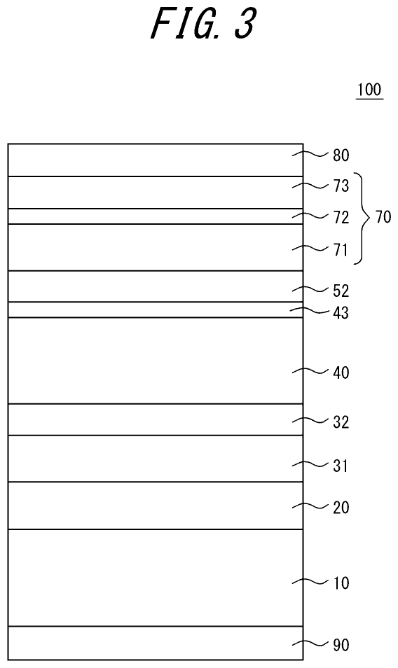

The following further describes specific forms that the III-V compound semiconductor light-emitting element according to the present disclosure can further include, but is not intended to limit the specific configuration of the III-V compound semiconductor light-emitting element according to the present disclosure. A III-V compound semiconductor light-emitting element 100 according to one embodiment of the present disclosure is described with reference to FIG. 3.

The III-V compound semiconductor light-emitting element 100 according to one embodiment of the present disclosure includes at least the light-emitting layer 40 including the laminate set forth above, and preferably further includes desired configurations from among a supporting substrate 10, an intervening layer 20, an n-type cladding layer 31, an n-side spacer layer 32, a p-side spacer layer 52, and a p-type semiconductor layer 70, in this order. Moreover, the III-V compound semiconductor light-emitting element 100 can further include a p-type electrode 80 on the p-type semiconductor layer 70 and an n-type electrode 90 at a rear surface of the supporting substrate 10. As a result of the light-emitting layer 40 being sandwiched between the n-type cladding layer 31 and the p-type semiconductor layer 70, passing of current to the light-emitting layer 40 causes light emission through combination of electrons and holes in the light-emitting layer 40.

### <Growth Substrate>

A growth substrate should be selected as appropriate from compound semiconductor substrates such as an InP substrate, an InAs substrate, a GaAs substrate, a GaSb substrate, and an InSb substrate in accordance with the composition of the light-emitting layer 40. It is preferable that the conductivity type of each substrate is set to correspond to the conductivity type of a semiconductor layer on the growth substrate. Examples of compound semiconductor substrates that can be adopted in the present embodiment include an n-type InP substrate and an n-type GaAs substrate.

### <Supporting Substrate>

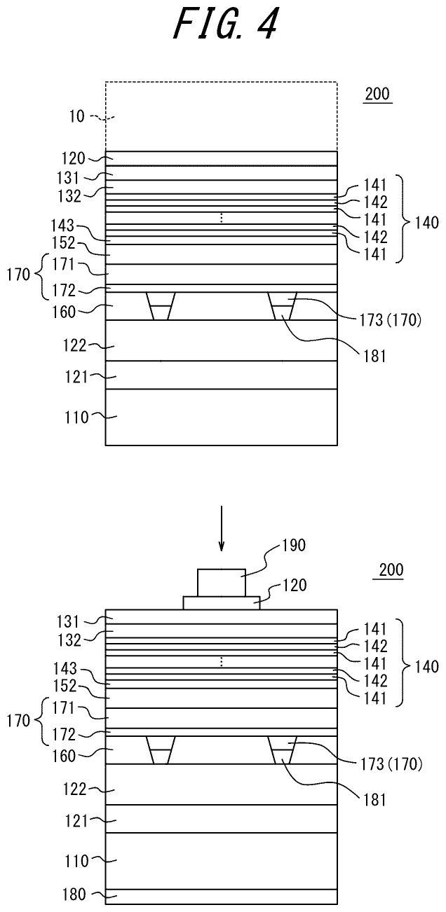

The supporting substrate 10 can be a growth substrate used to grow the light-emitting layer 40 on the supporting substrate 10. In a case in which a subsequently described bonding method is adopted, various types of substrates other than a growth substrate may be used as a supporting substrate 110 (refer to FIG. 4).

### <Intervening Layer>

An intervening layer 20 may be provided on the supporting substrate 10. In a case in which a growth substrate is used as the supporting substrate 10, the intervening layer 20 can be a III-V compound semiconductor layer. The intervening layer 20 can be used as an initial growth layer for epitaxial growth of a semiconductor layer on a supporting substrate 10 that serves as a growth substrate. Moreover, the intervening layer 20 can be used as a buffer layer for buffering lattice strain between a supporting substrate 10 that serves as a growth substrate and the n-type cladding layer 31, for example. Furthermore, the intervening layer 20 can also be used as an etching stop layer by performing lattice matching of the growth substrate and the intervening layer 20 while altering the semiconductor composition. For example, in a case in which the supporting substrate is an n-type InP substrate, the intervening layer 20 is preferably an n-type InGaAs layer. In this case, the composition ratio of In among the group III elements is preferably set as not less than 0.3 and not more than 0.7, and more preferably set as not less than 0.5 and not more than 0.6 in order to perform lattice matching of the intervening layer 20 with the InP growth substrate. Moreover, AlInAs, AlInGaAs, or InGaAsP may be adopted so long as composition ratios are set such that the lattice constant is close to that of the InP substrate to the same degree as with InGaAs described above. The intervening layer 20 may be a single layer or may be a composite layer (for example, a superlattice layer) with another layer.

<p-Type Semiconductor Layer>

A p-type semiconductor layer 70 can be provided on the light-emitting layer 40 and, as necessary, the p-side spacer layer 52. The p-type semiconductor layer 70 can include the previously described p-type cladding layer 71 and can also include a p-type contact layer 73 in order from the side where the light-emitting layer 40 is located. Provision of an intermediate layer 72 between the p-type cladding layer 71 and the p-type contact layer 73 is also preferable. The provision of the intermediate layer 72 makes it possible to ease lattice mismatch of the p-type cladding layer 71 and the p-type contact layer 73. The composition of a III-V compound semiconductor of the p-type semiconductor layer 70 should be set as appropriate in accordance with the composition of a III-V compound semiconductor of the light-emitting layer 40. For example, the p-type cladding layer may be p-type InP, the intermediate layer 72 may be p-type InGaAsP, and the p-type contact layer 73 may be p-type InGaAs that does not contain P in a case in which the light-emitting layer 40 is formed of an InGaAlAs semiconductor. Although no specific limitations are placed on the film thickness of each layer in the p-type semiconductor layer 70, the film thickness of the p-type cladding layer 71 can be not less than 1 μm and not more than 5 μm, for example, the film thickness of the intermediate layer 72 can be not less than 10 nm and not more than 200 nm, for example, and the film thickness of the p-type contact layer 73 can be not less than 50 nm and not more than 200 nm, for example.

### <Electrodes>

A p-type electrode 80 and an n-type electrode 90 can be provided on the p-type semiconductor layer 70 and at a rear surface of the supporting substrate 10, respectively. A metal material used to form each of the electrodes can be a typically used material, examples of which include metals such as Ti, Pt, and Au, and also metals (Sn, etc.) that form a eutectic alloy with gold. Moreover, the electrode pattern of each of the electrodes can be any pattern without any limitations.

Although the preceding description describes an embodiment in which a compound semiconductor substrate is used as a growth substrate and in which this growth substrate is used as the supporting substrate 10, the present disclosure is not limited thereto. After each semiconductor layer has been formed on a growth substrate, a bonding method may be adopted to remove the growth substrate while affixing a semiconductor substrate such as a Si substrate, a metal substrate such as Mo, W, or Kovar, any of various types of submount substrate in which AlN, etc., is used, or the like, and this substrate may be used as the supporting substrate of the III-V compound semiconductor light-emitting element according to the present disclosure (hereinafter, this method is referred to as a “bonding method”; refer to JP2018-006495A and JP2019-114650A). The following describes a case in which a bonding method is used with reference to FIG. 4. Note that the final two digits of reference signs in the drawings are the same as configurations that have already been described and repeated description thereof is omitted.

In a case in which a bonding method is used, each semiconductor layer is formed on a growth substrate 10, for example. After each semiconductor layer has been formed, a metal reflective layer 122 and a metal bonding layer 121 that is provided on a supporting substrate 110 are used to perform bonding, and then the growth substrate 10 is removed. An embodiment of the production method is described further below. The following provides a more specific description of the configuration of a III-V compound semiconductor light-emitting element 200 after removal of the growth substrate 10. Besides each electrode, other layers that are not III-V compound semiconductors can also be provided in the III-V compound semiconductor light-emitting element 200. For example, in a case in which a bonding method is used, formation can be performed such that a metal bonding layer 121 for supporting substrate bonding is included on a supporting substrate 110 formed of a Si substrate instead of the previously described initial growth layer, and then a p-type semiconductor layer 170, a light-emitting layer 140, and an n-type cladding layer 131 may be arranged sequentially thereon. Note that a metal reflective layer 122 can be provided on the metal bonding layer 121. Moreover, besides the III-V compound semiconductor layers, an ohmic electrode section 181 or a dielectric layer 160 surrounding ohmic electrode sections 181 present as island shapes can be provided on the metal reflective layer 122 as necessary. The dielectric material may be SiO₂, SiN, ITO, or the like.

It should be understood that the n-type/p-type of the conductivity types of the layers can of course be reversed relative to that in the preceding embodiment.

### (Production Method of III-V Compound Semiconductor Light-Emitting Element)

A method of producing the above-described III-V compound semiconductor light-emitting element according to the present disclosure includes a step of forming an n-type cladding layer 31, a step of forming a light-emitting layer 40 on the n-type cladding layer 31, a step of forming an electron blocking layer 43 on the light-emitting layer 40, and a step of forming a p-type cladding layer 71 on the electron blocking layer 43.

Steps of forming the various layers of the III-V compound semiconductor light-emitting element 100 that were described with reference to FIG. 3 may also be included as necessary. Since III-V compound semiconductor materials that can be used as barrier layers 41 and well layers 42, conditions for the composition wavelength difference and lattice constant difference thereof, film thicknesses, the number of stacked groups, and so forth are as previously described, repeated description thereof is omitted.

Each III-V compound semiconductor layer can be formed by a commonly known thin film growth method such as metal organic chemical vapor deposition (MOCVD), molecular beam epitaxy (MBE), or sputtering. In the case of an InGaAsP semiconductor, trimethylindium (TMIn) as an In source, trimethylgallium (TMGa) as a Ga source, arsine (AsH₃) as an As source, and phosphine (PH₃) as a P source, for example, can be used in a specific mixing ratio, and these source gases can be used to perform vapor phase growth while also using a carrier gas to thereby enable epitaxial growth of an InGaAsP semiconductor layer of desired thickness in accordance with the growth time. Moreover, trimethylaluminum (TMA) or the like may be used as an Al source in a case in which Al is used as a group III element, and TMSb (trimethylantimony) or the like may be used as an Sb source in a case in which Sb is used as a group V element. Furthermore, in a case in which p-type or n-type doping of a semiconductor layer is performed, a dopant source gas containing Si, Zn, or the like in constituent elements may also be used as desired.

Formation of metal layers such as an n-type electrode and a p-type electrode can be performed by commonly known techniques such as sputtering, electron beam evaporation, and resistance heating, for example. When a dielectric layer 160 is to be formed in a case in which a bonding method is adopted, a commonly known film formation method such as plasma CVD or sputtering may be used, and formation of irregularities can be performed by a commonly known etching method as necessary.

In a case in which the element illustrated in FIG. 4 is to be formed using a bonding method (refer to JP2018-006495A and JP2019-114650A mentioned above), the III-V compound semiconductor light-emitting element can be produced as described below, for example.

First, various III-V compound semiconductor layers including an etching stop layer 120, an n-type cladding layer 131, a light-emitting layer 140, a p-type cladding layer 171, an intermediate layer 172, and a p-type contact layer 173 are formed sequentially on a growth substrate 10 (note that FIG. 4 illustrates a state after bonding and thus appears upside down). Next, p-type ohmic electrode sections 181 dispersed in island shapes are formed on the p-type contact layer 173. Thereafter, a resist mask is formed at the p-type ohmic electrode sections 181 and at the peripheries thereof, and the p-type contact layer 173 is removed by wet etching or the like at locations other than locations where the ohmic electrode sections 181 have been formed to expose the intermediate layer 172. A dielectric layer 160 is then formed on the intermediate layer 172. The dielectric layer 160 is partially etched so as to expose the tops of the p-type ohmic electrode sections 181 and the intermediate layer 172 in peripheral sections of the p-type ohmic electrode sections 181. A metal reflective layer 122 is formed over the entire surface inclusive of on the p-type ohmic electrode sections 181, the intermediate layer 172 exposed at peripheral sections of the p-type ohmic electrode sections 181, and the dielectric layer 160 in regions where it has not been removed.

On the other hand, a conductive Si substrate or the like is used as a supporting substrate 110, and a metal bonding layer 121 is formed on the supporting substrate. The metal reflective layer 122 and the metal bonding layer 121 are arranged in opposition and are bonded through hot compression or the like. The growth substrate is then removed by etching to expose the etching stop layer 120. A bonding-type III-V compound semiconductor light-emitting element 200 can then be obtained by forming an n-type electrode 190 on the etching stop layer 120 and removing the etching stop layer 120 by etching with the exception of in an n-type electrode formation location; or by removing the etching stop layer 120 by etching with the exception of one section thereof and subsequently forming an n-type electrode 190 on the one section of the etching stop layer 120. As previously described, the n-type/p-type of conductivity types of the layers may be reversed relative to the example described above.

Although a present embodiment has been described above, embodiments are not limited to this embodiment, and various modifications can be made within the scope of the present disclosure using commonly known techniques. For example, each layer among the initial growth layer, the etching stop layer 120, the n-type cladding layer 131, the n-side spacer layer 132, the p-side spacer layer 152, the p-type cladding layer 171, the intermediate layer 172, and the p-type contact layer 173 may be a single layer, may be a composite layer (for example, a superlattice layer) with another layer, or may include a composition gradient. Moreover, a structure having a tunnel junction stacked in part thereof can also be incorporated. The following provides a more detailed description of the present disclosure using examples. However, the present disclosure is not in any way limited by the following examples.

### EXAMPLES

III-V Compound semiconductor light-emitting elements according to Examples 1 to 5 and Comparative Examples 1, 2, 3, 4, and 6, described below, were produced by a bonding method with 1,480 nm as a target central emission wavelength. Moreover, III-V compound semiconductor light-emitting elements according to Examples 6 and 7 and Comparative Examples 5 and 7, described below, were produced in the same manner with 1,330 nm as a target central emission wavelength.

### Example 1

Configurations of III-V compound semiconductor layers of a III-V compound semiconductor light-emitting element 200 according to Example 1 are described referring to reference signs in FIG. 4, and thicknesses and dopant concentrations thereof are shown in Table 2 for a state after growth on a growth substrate, prior to bonding to a supporting substrate described further below. A S-doped n-type InP substrate was used as a growth substrate 10. On a (100) face of the n-type InP substrate (S-doped; dopant concentration: 2.0×10¹⁸ atoms/cm³), an n-type InP layer of 100 nm in thickness and an n-type In_{0.57}Ga_{0.43}As layer of 20 nm in thickness (respectively an initial growth layer and an etching stop layer 120), an n-type InP layer of 3,500 nm in thickness (n-type cladding layer 131), an i-type InP layer of 100 nm in thickness (n-side spacer layer 132), a light-emitting layer 140 described in detail further below, an i-type InAlAs layer of 20 nm in thickness (electron blocking layer 143), an i-type InP layer of 300 nm in thickness (p-side spacer layer 152), a p-type InP layer of 2,400 nm in thickness (p-type cladding layer 171), a p-type In_{0.8}Ga_{0.2}As_{0.5}P_{0.5} layer of 50 nm in thickness (intermediate layer 172), and a p-type In_{0.57}Ga_{0.43}As layer of 100 nm in thickness (p-type contact layer 173) were formed sequentially by MOCVD. The n-type InP layer and n-type InGaAs layer (respectively an initial growth layer and an etching stop layer 120) and the n-type InP layer (n-type cladding layer 131) were subjected to Si doping such as to have a dopant concentration of 5.0×10¹⁷ atoms/cm³. The p-type InP layer (p-type cladding layer 171) was subjected to Zn doping such as to have a dopant concentration of 7.0×10¹⁷ atoms/cm³. The p-type InGaAsP layer (intermediate layer 172) and the p-type InGaAs layer (p-type contact layer 173) were subjected to Zn doping such as to have a dopant concentration of 1.5×10¹⁹ atoms/cm³.

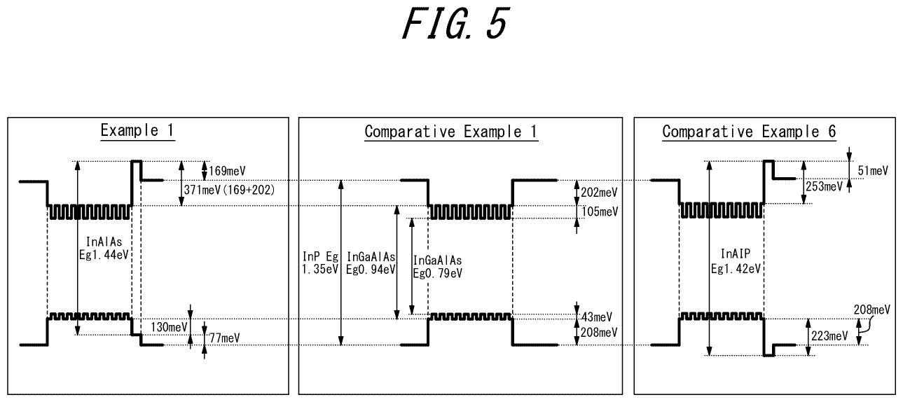

In formation of the light-emitting layer 140, an i-type Inₐ₁Ga_{b1}Al_{c1}As layer (barrier layer 141) serving as a barrier layer was first formed, and then 10 i-type Inₐ₂Ga_{b2}Al_{c2}As layers (well layers 142) serving as well layers and 10 i-type Inₐ₁Ga_{b1}Al_{c1}As layers (barrier layers 141) serving as barrier layers were stacked alternately so as to obtain a 10.5 group laminate. In other words, both extremities of the light-emitting layer 140 are barrier layers 141. The barrier layers 141 are each In_{0.5264}Ga_{0.3166}Al_{0.1570}As of 8 nm in thickness. In other words, the In composition ratio (a1) is 0.5264, the Ga composition ratio (b1) is 0.3166, and the Al composition ratio (c1) is 0.1570. Moreover, the well layers 142 are each In_{0.5435}Ga_{0.3976}Al_{0.0589}As of 10 nm in thickness. In other words, the In composition ratio (a2) is 0.5435, the Ga composition ratio (b2) is 0.3976, and the Al composition ratio (c2) is 0.0589. In addition, lattice constants were calculated as previously described, and the band structure was calculated using simulation software (SiLENSe) produced by STR Japan K.K. Values for the thicknesses, composition ratios, composition wavelengths, and lattice constants of the barrier layers 141 and the well layers 142, the carrier density of the p-type InP layer (p-type cladding layer 171), and the composition of the electron blocking layer (EBL) are recorded in Table 3. In band gaps taking the cladding layer Ec in Example 1 as a reference, values obtained through subtraction of a larger band gap from a smaller band gap were, at the conduction band-side, 0.371 eV for Ec−Ecb, 0.169 eV for Ec−Ecs, and 0.371 eV-0.169 eV=0.202 eV for Ecs−Ecb. Moreover, at the valence band-side, the values were 0.130 eV for Evb−Ev, 0.077 eV for Ev−Evs, and 0.130 eV+0.077 eV=0.208 eV for Evb−Evs. These values are recorded in Table 4. Note that the compositions of the layers in Example 1 described above are values that were measured through SIMS analysis. For each layer in the light-emitting layer, a solid phase ratio of that layer was confirmed by SIMS analysis after the light-emitting layer had been exposed. Moreover, the band structure of the light-emitting layer and semiconductor layers before and after the light-emitting layer in Example 1 as calculated using simulation software is illustrated together with calculation results for Comparative Example 1 in FIG. 5.

TABLE 2

| | | | | Dopant | | |
|---|---|---|---|---|---|---|
| | | | Thickness | concentration | | |
| Semiconductor layer | | Composition | nm | cm⁻³ | | |
| p-Type contact layer | | p-InGaAs | 100 | 1.5 × 10¹⁹ | | |
| Intermediate layer | | p-InGaAsP | 50 | 5.0 × 10¹⁸ | | |
| p-Type cladding layer | | p-InP | 2400 | 7.0 × 10¹⁷ | | |
| p-Side spacer layer | | i-InP | 300 | — | | |
| Electron blocking layer | | i-InAlAs | 20 | — | | |
| Light-emitting | Barrier layer | i-InGaAlAs | 8 | — | | |
| layer (MQW | Well layer | i-InGaAlAs | 10 | — | | |
| active layer) | Barrier layer | i-InGaAlAs | 8 | — | | |
| | Well layer | i-InGaAlAs | 10 | — | | |
| | . | | | | {close oversize brace} | (Barrier layer + well |
| | . | | | | | layer) × 10 groups |
| | . | | | | | |
| | Barrier layer | i-InGaAlAs | 8 | — | | |
| | Well layer | i-InGaAlAs | 10 | — | | |
| | Barrier layer | i-InGaAlAs | 8 | — | | |

| | | | |
|---|---|---|---|
| n-Side spacer layer | i-InP | 100 | — |
| n-Type cladding layer | n-InP | 3500 | 5.0 × 10¹⁷ |
| Etching stop layer | n-InGaAs | 20 | 5.0 × 10¹⁷ |
| Initial growth layer | n-InP | 100 | 5.0 × 10¹⁷ |
| Growth substrate | n-InP | — | 2.0 × 10¹⁸ |

p-Type ohmic electrode sections 181 (Au/AuZn/Au; total thickness: 530 nm) were formed in dispersed island shapes on the p-type contact layer. Note that in island pattern formation, a resist pattern was formed, ohmic electrode sections 181 were then vapor deposited, and lift-off of the resist pattern was performed to form the island pattern. The proportion constituted by area of the p-type ohmic electrode sections 181 relative to chip area (contact area ratio) is 0.95% and the chip size is 280 μm-square.

Next, a resist mask was formed at the p-type ohmic electrode sections 181 and the peripheries thereof, and the p-type contact layer 173 was removed through tartaric acid-hydrogen peroxide wet etching at locations other than the locations where the ohmic electrode sections 181 had been formed to expose the intermediate layer 172. Thereafter, a dielectric layer 160 (thickness: 700 nm) formed of SiO₂ was formed over the entirety of the intermediate layer 172 by plasma CVD. A window pattern having a shape provided with a width of 3 μm in a width direction and a longitudinal direction in a region above each of the p-type ohmic electrode sections 181 was formed by a resist, and the dielectric layer 160 was removed by wet etching using BHF at the p-type ohmic electrode sections 181 and the peripheries thereof to expose the tops of the p-type ohmic electrode sections 181 and the intermediate layer 172 at the peripheries of the p-type ohmic electrode sections 181.

Next, a metal reflective layer 122 was formed over the entirety of the intermediate layer 172 (tops of p-type ohmic electrode sections 181, top of dielectric layer 160, and intermediate layer 172 exposed at peripheries of p-type ohmic electrode sections 181) by vapor deposition. The thicknesses of metal layers in the metal reflective layer (Ti/Au/Pt/Au) are, in order, 2 nm, 650 nm, 100 nm, and 900 nm. On the other hand, a metal bonding layer 121 was formed on a conductive Si substrate (thickness: 200 μm) serving as a supporting substrate. The thicknesses of metal layers in the metal bonding layer (Ti/Pt/Au) are, in order, 650 nm, 10 nm, and 900 nm.

The metal reflective layer 122 and the metal bonding layer 121 were arranged in opposition and were hot compression bonded at 315° C. The n-type InP substrate 10 was then removed by wet etching using dilute hydrochloric acid.

An n-type electrode 190 (Au (thickness: 10 nm)/Ge (thickness: 33 nm)/Au (thickness: 57 nm)/Ni (thickness: 34 nm)/Au (thickness: 800 nm)/Ti (thickness: 100 nm)/Au (thickness: 1,000 nm)) was then formed as a wiring section of an upper surface electrode on the etching stop layer 120 through resist pattern formation, n-type electrode vapor deposition, and resist pattern lift-off. A pad section (Ti (thickness: 150 nm)/Pt (thickness: 100 nm)/Au (thickness: 2,500 nm)) was then further formed on the n-type electrode to form an upper surface electrode pattern. The etching stop layer 120 was then removed by wet etching with the exception of that directly below the n-type electrode 190 and in proximity thereto, and surface roughening treatment was performed. Thereafter, a dielectric protective film (not illustrated) was formed over the upper surface and the side surface of the III-V compound semiconductor light-emitting element 200 with the exception of an upper surface of the pad section.

### Example 2, Example 3, and Example 4

III-V Compound semiconductor light-emitting elements according to Example 2, Example 3, and Example 4 were obtained in the same way as in Example 1 with the exception that the thickness of the spacer layer 152 was changed to 200 nm or 100 nm or the spacer layer was omitted.

### Example 5

A III-V compound semiconductor light-emitting element according to Example 5 was obtained in the same way as in Example 1 with the exception that the composition of the barrier layers 141 was changed from In_{0.5264}Ga_{0.3166}Al_{0.1570}As to In_{0.5264}Ga_{0.1626}Al_{0.3110}As.

### Example 6

A III-V compound semiconductor light-emitting element according to Example 6 was obtained in the same way as in Example 1 with the exception that the composition of the barrier layers 141 was changed from In_{0.5264}Ga_{0.3166}Al_{0.1570}As to In_{0.5453}Ga_{0.2440}Al_{0.2107}As and the composition of the well layers 142 was changed from In_{0.5435}Ga_{0.3976}Al_{0.0589}As to In_{0.5601}Ga_{0.3088}Al_{0.1311}As.

### Example 7

A III-V compound semiconductor light-emitting element according to Example 7 was obtained in the same way as in Example 6 with the exception that the thickness of the spacer layer 152 was changed to 100 nm.

### Comparative Example 1

A III-V compound semiconductor light-emitting element according to Comparative Example 1 was obtained in the same way as in Example 1 with the exception that the thickness of the spacer layer 152 was changed to 320 nm and the electron blocking layer 143 was not provided.

### Comparative Example 2 and Comparative Example 3

III-V Compound semiconductor light-emitting elements according to Comparative Example 2 and Comparative Example 3 were obtained in the same way as in Comparative Example 1 with the exception that the thickness of the spacer layer 152 was changed to 100 nm or the spacer layer was omitted.

### Comparative Example 4

A III-V compound semiconductor light-emitting element according to Comparative Example 4 was obtained in the same way as in Example 5 with the exception that the spacer layer 152 and the electron blocking layer 143 were not provided.

### Comparative Example 5

A III-V compound semiconductor light-emitting element according to Comparative Example 5 was obtained in the same way as in Example 5 with the exception that the thickness of the spacer layer 152 was changed to 320 nm and the electron blocking layer 143 was not provided.

### Comparative Example 6

A III-V compound semiconductor light-emitting element according to Comparative Example 6 was obtained in the same way as in Example 1 with the exception that the composition of the electron blocking layer 143 was changed to In_{0.95}Al_{0.05}P.

### Comparative Example 7

A III-V compound semiconductor light-emitting element according to Comparative Example 7 was obtained in the same way as in Example 6 with the exception that the composition of the electron blocking layer 143 was changed to In_{0.95}Al_{0.05}P.

The composition wavelengths and lattice constants calculated from the composition of the barrier layers 141 and the composition of the well layers 142 for each example and comparative example are recorded in Table 3. Band gaps of Ec−Ecb, Ec−Ecs, and Ecs−Ecb at the conduction band-side and band gaps of Evb−Ev, Ev−Evs, and Evb−Evs at the valence band-side are recorded in Table 4.

TABLE 3

| | | Well layer | | | | | | | Barrier layer | | |
|---|---|---|---|---|---|---|---|---|---|---|---|
| | | | Group III | | | Group V | | | | Group III | |
| | Target | | In | Ga | Al | As | Composition | | | In | Ga |
| | wave- | Thick- | Compo- | Compo- | Compo- | Compo- | wave- | Lattice | Thick- | Compo- | Compo- |
| | length | ness | sition | sition | sition | sition | length | constant | ness | sition | sition |
| | [nm] | [nm] | ratio | ratio | ratio | ratio | [nm] | [nm] | [nm] | ratio | ratio |
| Comparative | 1480 | 10 | 0.5435 | 0.3976 | 0.0589 | 1.0000 | 1565.0 | 0.5873 | 8 | 0.5264 | 0.3166 |
| Example 1 | | | | | | | | | | | |
| Comparative | | 10 | 0.5435 | 0.3976 | 0.0589 | 1.0000 | 1565.0 | 0.5873 | 8 | 0.5264 | 0.3166 |
| Example 2 | | | | | | | | | | | |
| Comparative | | 10 | 0.5435 | 0.3976 | 0.0589 | 1.0000 | 1565.0 | 0.5873 | 8 | 0.5264 | 0.3166 |
| Example 3 | | | | | | | | | | | |
| Example 1 | | 10 | 0.5435 | 0.3976 | 0.0589 | 1.0000 | 1565.0 | 0.5873 | 8 | 0.5264 | 0.3166 |
| Comparative | | 10 | 0.5435 | 0.3976 | 0.0589 | 1.0000 | 1565.0 | 0.5873 | 8 | 0.5264 | 0.3166 |
| Example 6 | | | | | | | | | | | |
| Example 2 | | 10 | 0.5435 | 0.3976 | 0.0589 | 1.0000 | 1565.0 | 0.5873 | 8 | 0.5264 | 0.3166 |
| Example 3 | | 10 | 0.5435 | 0.3976 | 0.0589 | 1.0000 | 1565.0 | 0.5873 | 8 | 0.5264 | 0.3166 |
| Example 4 | | 10 | 0.5435 | 0.3976 | 0.0589 | 1.0000 | 1565.0 | 0.5873 | 8 | 0.5264 | 0.3166 |
| Comparative | | 10 | 0.5435 | 0.3976 | 0.0589 | 1.0000 | 1565.0 | 0.5873 | 8 | 0.5264 | 0.1626 |
| Example 4 | | | | | | | | | | | |
| Example 5 | | 10 | 0.5435 | 0.3976 | 0.0589 | 1.0000 | 1565.0 | 0.5873 | 8 | 0.5264 | 0.1626 |
| Comparative | 1330 | 10 | 0.5601 | 0.3088 | 0.1311 | 1.0000 | 1375.0 | 0.5880 | 8 | 0.5453 | 0.2440 |
| Example 5 | | | | | | | | | | | |
| Example 6 | | 10 | 0.5601 | 0.3088 | 0.1311 | 1.0000 | 1375.0 | 0.5880 | 8 | 0.5453 | 0.2440 |
| Comparative | | 10 | 0.5601 | 0.3088 | 0.1311 | 1.0000 | 1375.0 | 0.5880 | 8 | 0.5453 | 0.2440 |
| Example 7 | | | | | | | | | | | |
| Example 7 | | 10 | 0.5601 | 0.3088 | 0.1311 | 1.0000 | 1375.0 | 0.5880 | 8 | 0.5453 | 0.2440 |

| | Barrier layer | | | | | | |
|---|---|---|---|---|---|---|---|
| | Group III | Group V | | | | | |
| | Al | As | Composition | | Carrier | | |
| | Compo- | Compo- | wave- | Lattice | density | | EBL |
| | sition | sition | length | constant | (p-InP) | | compo- |
| | ratio | ratio | [nm] | [nm] | ×10¹⁷ | EBL | sition |
| Comparative | 0.1570 | 1.0000 | 1318.2 | 0.5866 | 7.0 | No | — |
| Example 1 | | | | | | | |
| Comparative | 0.1570 | 1.0000 | 1318.2 | 0.5866 | 7.0 | No | — |
| Example 2 | | | | | | | |
| Comparative | 0.1570 | 1.0000 | 1318.2 | 0.5866 | 7.0 | No | — |
| Example 3 | | | | | | | |
| Example 1 | 0.1570 | 1.0000 | 1318.2 | 0.5866 | 7.0 | Yes | In_{0.52}Al_{0.48}As |
| Comparative | 0.1570 | 1.0000 | 1318.2 | 0.5866 | 7.0 | Yes | In_{0.95}Al_{0.05}P |
| Example 6 | | | | | | | |
| Example 2 | 0.1570 | 1.0000 | 1318.2 | 0.5866 | 7.0 | Yes | In_{0.52}Al_{0.48}As |
| Example 3 | 0.1570 | 1.0000 | 1318.2 | 0.5866 | 7.0 | Yes | In_{0.52}Al_{0.48}As |
| Example 4 | 0.1570 | 1.0000 | 1318.2 | 0.5866 | 7.0 | Yes | In_{0.52}Al_{0.48}As |
| Comparative | 0.3110 | 1.0000 | 1060.0 | 0.5866 | 7.0 | No | — |
| Example 4 | | | | | | | |
| Example 5 | 0.3110 | 1.0000 | 1060.0 | 0.5866 | 7.0 | Yes | In_{0.52}Al_{0.48}As |
| Comparative | 0.2107 | 1.0000 | 1181.4 | 0.5874 | 7.0 | No | — |
| Example 5 | | | | | | | |
| Example 6 | 0.2107 | 1.0000 | 1181.4 | 0.5874 | 7.0 | Yes | In_{0.52}Al_{0.48}As |
| Comparative | 0.2107 | 1.0000 | 1181.4 | 0.5874 | 7.0 | Yes | In_{0.95}Al_{0.05}P |
| Example 7 | | | | | | | |
| Example 7 | 0.2107 | 1.0000 | 1181.4 | 0.5874 | 7.0 | Yes | In_{0.52}Al_{0.48}As |

TABLE 4

| | Target | Ec conduction band | | | Ev valence band | | | Spacer layer | Light emission output Po | |
|---|---|---|---|---|---|---|---|---|---|---|
| | wave- | Ec − | Ec − | Ecs − | Evb − | Ev − | Evb − | Thick- | (If = | (If = |
| | length | Ecb | Ecs | Ecb | Ev | Evs | Evs | ness | 30 mA) | 36 mA) |
| | [nm] | [eV] | [eV] | [eV] | [eV] | [eV] | [eV] | [nm] | [mW] | [mW |
| Comparative | 1480 | — | — | 0.202 | — | — | 0.208 | 320 | 3.84 | 4.38 |
| Example 1 | | | | | | | | | | |
| Comparative | | — | — | 0.202 | — | — | 0.208 | 100 | No light emission | |
| Example 2 | | | | | | | | | | |
| Comparative | | — | — | 0.202 | — | — | 0.208 | 0 | No light emission | |
| Example 3 | | | | | | | | | | |
| Example 1 | | 0.371 | 0.169 | 0.202 | 0.130 | 0.077 | 0.208 | 300 | 3.94 | 4.50 |
| Comparative | | 0.253 | 0.051 | 0.202 | 0.223 | −0.015 | 0.208 | 300 | 3.87 | 4.29 |
| Example 6 | | | | | | | | | | |
| Example 2 | | 0.371 | 0.169 | 0.202 | 0.130 | 0.077 | 0.208 | 200 | 3.84 | 4.38 |
| Example 3 | | 0.371 | 0.169 | 0.202 | 0.130 | 0.077 | 0.208 | 100 | 3.78 | 4.33 |
| Example 4 | | 0.371 | 0.169 | 0.202 | 0.130 | 0.077 | 0.208 | 0 | 3.75 | 4.28 |
| Comparative | | — | — | 0.035 | — | — | 0.145 | 320 | 3.95 | 4.51 |
| Example 4 | | | | | | | | | | |
| Example 5 | | 0.204 | 0.169 | 0.035 | 0.068 | 0.077 | 0.145 | 300 | 4.00 | 4.57 |
| Comparative | 1330 | — | — | 0.154 | — | — | 0.191 | 320 | 4.55 | 17.21 |
| Example 5 | | | | | | | | | | |
| Example 6 | | 0.323 | 0.169 | 0.154 | 0.114 | 0.077 | 0.191 | 300 | 4.81 | 17.86 |
| Comparative | | 0.205 | 0.051 | 0.202 | 0.206 | −0.015 | 0.208 | 300 | 4.48 | 16.48 |
| Example 7 | | | | | | | | | | |
| Example 7 | | 0.323 | 0.169 | 0.154 | 0.114 | 0.077 | 0.191 | 100 | 4.82 | 17.11 |

| | | | | | | Light emission | |
|---|---|---|---|---|---|---|---|
| | Forward voltage Vf | | Central emission | | | output relative | |
| | (If = | (If = | wavelength λp | | | to injected power | |
| | 30 mA) | 36 mA) | avg. | Max − Min | FWHM | Po/(Vf · If) | |
| | [V] | [V] | [nm] | [nm | [nm] | (If = 30 mA) | (If = 36 mA) |
| Comparative | 1.04 | 1.07 | 1501 | 3 | 110 | 0.123 | 0.114 |
| Example 1 | | | | | | | |
| Comparative | No light emission | | | | | | |
| Example 2 | | | | | | | |
| Comparative | No light emission | | | | | | |
| Example 3 | | | | | | | |
| Example 1 | 0.95 | 0.99 | 1497 | 4 | 109 | 0.138 | 0.127 |
| Comparative | 1.09 | 1.15 | 1498 | 4 | 107 | 0.119 | 0.103 |
| Example 6 | | | | | | | |
| Example 2 | 0.92 | 0.95 | 1500 | 4 | 108 | 0.139 | 0.128 |
| Example 3 | 0.88 | 0.90 | 1499 | 3 | 109 | 0.144 | 0.133 |
| Example 4 | 0.84 | 0.86 | 1499 | 3 | 109 | 0.149 | 0.138 |
| Comparative | 1.04 | 1.07 | 1487 | 3 | 106 | 0.127 | 0.117 |
| Example 4 | | | | | | | |
| Example 5 | 0.95 | 0.98 | 1484 | 4 | 105 | 0.141 | 0.129 |
| Comparative | 0.93 | 1.15 | 1338 | 0 | 73 | 0.163 | 0.150 |
| Example 5 | | | | | | | |
| Example 6 | 0.95 | 1.12 | 1337 | 1 | 72 | 0.168 | 0.160 |
| Comparative | 0.99 | 1.24 | 1338 | 1 | 72 | 0.151 | 0.133 |
| Example 7 | | | | | | | |
| Example 7 | 0.90 | 1.04 | 1336 | 1 | 71 | 0.178 | 0.164 |

### (Evaluation of Light Emission Characteristics)

For each of the III-V compound semiconductor light-emitting elements according to Examples 1 to 7 and Comparative Examples 1 to 7, the forward voltage Vf (V) and the light emission output Po (mW) according to an integrating sphere were measured for when forward currents If (mA) of 30 mA and 36 mA were passed using a constant current/voltage power supply. The central emission wavelength λp (nm) and the full width at half maximum (FWHM; units: nm) according to a spectral analyzer (AQ6374 produced by Yokogawa Test & Measurement Corporation) were also measured. Note that in these measurements, an average value of measurement results for three samples was determined. Next, the light emission output was divided by the injected power at that time to calculate Po/(Vf·If), the value of which was taken as an index of light emission output relative to injected power. The various measurement results and calculation results are shown in Table 4.

### (Dopant Diffusion Evaluation)

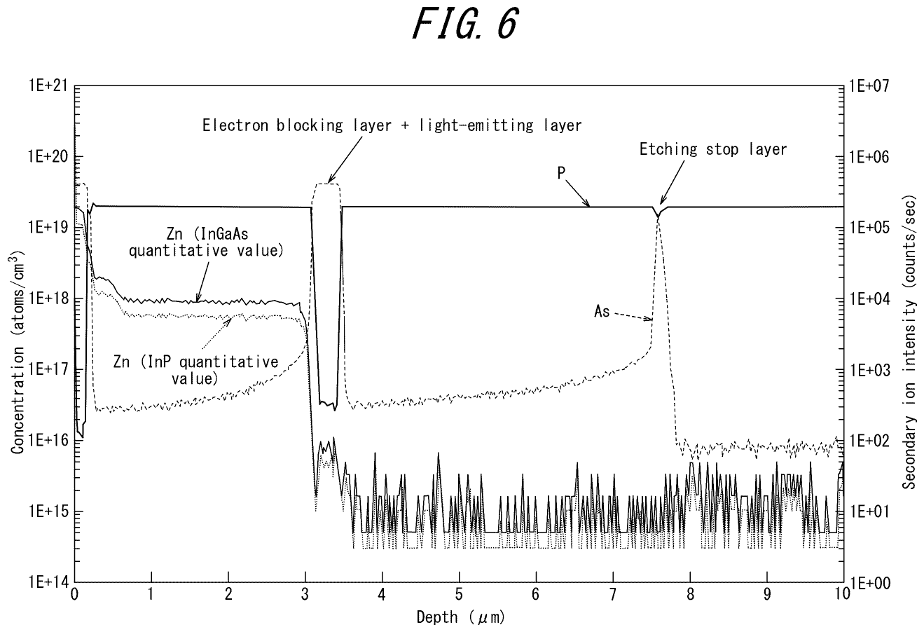

The state of dopant diffusion in the light-emitting element of Example 3, as a representative example, was measured by SIMS. The measurement results are illustrated in FIG. 6.

It can be seen from the results in Table 4 that the examples satisfying the band gap relationships according to the present disclosure each have a large light emission output relative to injected power. Moreover, by focusing on Examples 1 to 3 in which an electron blocking layer is provided and that differ only in terms of the thickness of a spacer layer, it can be seen that light emission output relative to injected power increases as spacer layer thickness decreases. In contrast, Comparative Examples 1 to 3 in which an electron blocking layer is not provided have a small light emission output relative to injected power or have no light emission. There is same result for this in the relationship of Example 5 and Comparative Example 4. Moreover, with regards to Examples 6 and 7 and Comparative Example 5 in which the light emission wavelength is around 1,330 nm, light emission output relative to injected power increases with decreasing spacer layer thickness in Examples 5 and 6 in which an electron blocking layer is provided, whereas light emission output relative to injected power is small compared to the examples in Comparative Example 5 in which an electron blocking layer is not provided.

Furthermore, it can be seen through reference to FIG. 6 that in Example 3, the concentration of Zn, which serves as a dopant in the p-type cladding layer (InP), decreases rapidly in the electron blocking layer and is also maintained at an extremely low concentration (1×10¹⁶ atoms/cm³ or less as InGaAs quantitative value; 7×10¹⁵ atoms/cm³ or less as InP quantitative value) in the light-emitting layer adjacent thereto. Although not illustrated, a Zn concentration exceeding 1×10¹⁶ atoms/cm³ is observed at the p-type layer-side of a light-emitting layer in Comparative Example 2 and Comparative Example 3 in which an electron blocking layer according to the present disclosure is absent and in which the spacer layer is thin. Increased Zn diffusion compared to Example 1 is also observed in Comparative Example 6 in which an electron blocking layer is formed of InAlP. It can be understood from these results that Zn diffusion is inhibited in the examples through the presence of an electron blocking layer having As as a group V element.

### INDUSTRIAL APPLICABILITY

The present disclosure is useful in terms of enabling the provision of a III-V compound semiconductor light-emitting element having good light emission output relative to injected power compared to conventional light-emitting elements and a method of producing the same.

### REFERENCE SIGNS LIST

10 supporting substrate
20 intervening layer
31 n-type cladding layer
32 n-side spacer layer
40 light-emitting layer
41 barrier layer
42 well layer
43 electron blocking layer
52 p-side spacer layer
60 dielectric layer
70 p-type semiconductor layer
71 p-type cladding layer
72 intermediate layer
73 p-type contact layer
80 p-type electrode
90 n-type electrode
100 III-V compound semiconductor light-emitting element

1. A III-V compound semiconductor light-emitting element comprising an n-type cladding layer, a light-emitting layer, and a p-type cladding layer in stated order, wherein
an undoped electron blocking layer is included between the light-emitting layer and the p-type cladding layer,
the light-emitting layer has a layered structure in which a barrier layer and a well layer are stacked repeatedly,
(i) at a conduction band, a band gap (Ec) of the electron blocking layer is larger than a band gap (Ecb) of the barrier layer and a band gap (Ecs) of the p-type cladding layer, and the band gap (Ecs) of the p-type cladding layer is larger than the band gap (Ecb) of the barrier layer, and
(ii) at a valence band, a band gap (Ev) of the electron blocking layer is between a band gap (Evb) of the barrier layer and a band gap (Evs) of the p-type cladding layer.

2. The III-V compound semiconductor light-emitting element according to claim 1, wherein the electron blocking layer and the p-type cladding layer have a different principal group V element from each other.

3. The III-V compound semiconductor light-emitting element according to claim 1, wherein an undoped spacer layer is included between the electron blocking layer and the p-type cladding layer, and the p-type cladding layer and the spacer layer have the same principal group V element as each other.

4. The III-V compound semiconductor light-emitting element according to claim 3, wherein the spacer layer has a thickness of 300 nm or less.

5. The III-V compound semiconductor light-emitting element according to claim 1, wherein the electron blocking layer and the p-type cladding layer are adjacent.

6. A method of producing the III-V compound semiconductor light-emitting element according to claim 1, comprising:
a step of forming the n-type cladding layer;
a step of forming the light-emitting layer on the n-type cladding layer;
a step of forming the electron blocking layer on the light-emitting layer; and
a step of forming the p-type cladding layer on the electron blocking layer.

7. The method of producing the III-V compound semiconductor light-emitting element according to claim 6, wherein the electron blocking layer and the p-type cladding layer have a different principal group V element from each other.

8. The method of producing the III-V compound semiconductor light-emitting element according to claim 6, wherein an undoped spacer layer is included between the electron blocking layer and the p-type cladding layer, and the p-type cladding layer and the spacer layer have the same principal group V element as each other.

9. The method of producing the III-V compound semiconductor light-emitting element according to claim 6, wherein the spacer layer has a thickness of 300 nm or less.

10. The method of producing the III-V compound semiconductor light-emitting element according to claim 6, wherein the electron blocking layer and the p-type cladding layer are adjacent.
